(19) United States
(12) Patent Application Publication
(10) Pub. No.: US 2026/0163559 A1
(43) Pub. Date: Jun. 11, 2026

(54) SYSTEMS AND METHODS FOR SIGNAL MODULATION AND SWITCHING

(71) Applicant: Aeromotive, LLC

(72) Inventors: Brian Baskin, Discovery Bay, CA (US); Carl Casanova, Newbury Park, CA (US)

(73) Assignee: Aeromotive, LLC, (omitted)

(21) Appl. No.: 19/413,869

(22) Filed: Dec. 9, 2025

Related U.S. Application Data
(60) Provisional application No. 63/729,821, filed on Dec. 9, 2024.

(51) Int. Cl. H03K 3/017; H03H 7/06

(52) U.S. Cl. CPC H03K 3/017; H03H 7/06

(57) ABSTRACT

A modulator and associated methods are disclosed for generating a shaped switching output based on an incoming control signal. The modulator includes a limiting amplifier that constrains the amplitude of the input waveform using positive and negative reference inputs, a detector that identifies positive portions or transitions of the limited waveform, and an RC timing circuit that produces a decaying waveform according to a selected time constant. A comparison stage evaluates the decaying waveform against a reference threshold to form a shaped pulse, which is amplified and applied to an output switching stage to drive a load. Depending on the input frequency, duty cycle, and timing relationships, the modulator can produce continuous outputs, discrete pulses, or pulse-width-modulated signals. In various embodiments, the modulator conditions PWM or other command signals for use with inductive or resistive devices such as motors, pumps, or fuel-delivery systems.

### CROSS-REFERENCE TO RELATED APPLICATIONS

This application claims the benefit of U.S. Provisional Patent Application Ser. No. 63/729,821, filed Dec. 9, 2024, the disclosure of which is hereby incorporated herein in its entirety by reference.

### BACKGROUND

Electronic control systems for motors, pumps, and other electrically powered loads often rely on switching or modulation of an input signal to achieve a desired output response. In many applications, an incoming control signal such as a square wave, pulse train, or other periodic waveform is used to establish a switching frequency or duty cycle for controlling a downstream device. For example, in systems driving electrical motors, such as those used in fuel-delivery systems, industrial actuators, and general inductive or resistive loads, it is often desirable to command a device through a defined range of output states using a shaped, conditioned, or otherwise modified control waveform.

Conventional circuits for performing switching and modulation functions can introduce undesirable effects. For example, simple transistor-based switching circuitry may replicate an incoming waveform but fail to provide adequate shaping, filtering, or edge conditioning, resulting in switching noise, unstable drive characteristics, or erratic operation of the load device. In other implementations, a signal may require modification to a different frequency, an altered duty cycle, or a reduced amplitude, but known modulation approaches may not provide stable behavior under varying load conditions. These issues are particularly problematic in systems where inductive loads, such as pumps or motors, are more sensitive to abrupt changes in drive waveforms, or where noise and irregularities propagate downstream and affect overall system performance.

Furthermore, in many cases an input control waveform may be available, but a different output waveform is required for proper operation of a controlled device. Converting an incoming signal having one form to a clean, well-defined, and reliably reproducible output wave of another form can typically require multiple signal processing stages, and without, for example, proper amplification limits, pulse shaping, filtering, and/or controlled switching, a resulting conditioned signal may exhibit unintended noise or distortions, or may lack the timing characteristics necessary for accurate downstream control.

Thus, it can be seen that there remains a need in the art for a system and method for receiving an input waveform and producing from it a properly shaped, filtered, and stable modulation output suitable for driving a wide range of loads.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the invention will be apparent from the following detailed description of the embodiments and the accompanying drawing figures.

The present invention relates to systems, circuits, and methods for generating a shaped switching output based on an incoming electrical control signal. In various embodiments as described herein, a modulator receives an input waveform that may include a pulse-width modulated (PWM) signal, a waveform of varying frequency, or another control signal representative of a desired operational condition. The modulator circuitry conditions the input waveform through a sequence of limiting, detection, timing, and comparison stages configured to produce a controlled pulse or switching waveform for driving a downstream load.

In one exemplary embodiment, the modulator includes a limiting amplifier configured to limit the amplitude of the incoming signal based on positive and negative reference inputs. The output of the limiting amplifier is supplied to a detector, such as a half-wave detector, which produces a detection output corresponding to the positive portions or transitions of the limited waveform. A timing stage charges and discharges a capacitor to create a decaying waveform according to a resistive and a capacitive (RC) time constant. The decaying waveform is compared to an input reference, and the comparison result is amplified and limited to create a shaped waveform with a duration that reflects the relationship between the RC time constant, the input waveform, and the reference threshold. A switching stage receives the shaped waveform and generates a switching output suitable for driving various types of loads.

In various embodiments, the shaped switching output may operate in several different modes depending on the characteristics of the input signal. For example, when the frequency of the input signal is substantially higher than the cutoff frequency of a low-pass filter, the output may reflect duty cycle dependent or frequency dependent behavior. When the off time of the limited waveform is substantially less than the RC time constant, the switching stage may produce a continuous output. In other operating conditions, the modulator may generate a sequence of pulses having widths determined by the RC time constant or by other timing relationships in the input signal.

The modulator may be used in a wide variety of applications, such as controlling devices having inductive or resistive loads, such as motors, pumps, actuators, and other electromechanical devices. In some embodiments, the modulator may be a part of a fuel pump control system where a PWM command signal from an engine controller or other subsystem is conditioned and shaped to provide a controlled switching output to a fuel pump. The shaped switching output allows the fuel pump to deliver fuel according to the characteristics of the PWM command signal and the timing relationships generated within the modulator circuitry.

While several exemplary embodiments and applications are described herein, it should be understood that the modulator may be implemented using different circuit arrangements, different timing values, or different reference thresholds, and may be adapted for use with different types of loads or signaling environments. Variations of the embodiments as described in the present application are thus within the scope of the present invention.

### BRIEF DESCRIPTION OF THE DRAWING FIGURES

Embodiments of the invention are described in detail below with reference to the attached drawing figures, wherein:

FIG. 1 is a block diagram of modulator circuitry in accordance with an exemplary embodiment of the present invention.

FIG. 2 is a block diagram of a system in which a modulator as depicted in FIG. 1 receives a control signal and drives a representative electrical load, in accordance with an exemplary embodiment of the present invention.

FIG. 3 is a block diagram of a multi-load control configuration in which multiple modulators, each configured as the modulator of FIG. 1, receive one or more control signals from a control signal source and drive corresponding electrical loads.

FIG. 4 is a block diagram of a fuel-pump control system in which a modulator as shown in FIG. 1 receives a PWM command signal from a pump control source and produces a shaped switching output for driving an electromechanical fuel pump.

FIG. 5 is a flowchart depicting an exemplary sequence of functional steps performed by the modulator circuitry of FIG. 1, including limiting an input waveform, detecting transitions, generating an RC-based decaying waveform, comparing the waveform to a reference threshold, shaping the resulting pulse, and supplying a switching output to a load.

The drawing figures do not limit the invention to the specific embodiments disclosed and described herein. The drawings are not necessarily to scale, but are intended to clearly illustrate the principles of the invention.

### DETAILED DESCRIPTION

The following detailed description references the accompanying drawings that illustrate specific exemplary embodiments in which the invention can be practiced. The embodiments are intended to describe aspects of the invention in sufficient detail to enable those skilled in the art to practice the invention. Other embodiments can be utilized, and changes can be made without departing from the scope of the invention. The following detailed description is, therefore, not to be taken in a limiting sense. The scope of the invention is defined only by the appended claims, along with the full scope of the equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included in those other embodiments. Thus, the technology can include a variety of combinations and/or integrations of the embodiments described herein. In various embodiments described herein, multifunction modulators produce a multitude of different switched outputs and modulations in which the modulation function is dependent on the input signals in various ways.

The subject matter of select embodiments of the invention is described with specificity herein to meet statutory requirements. References to steps or components should not be interpreted as requiring any particular order unless expressly stated. Similarly, terms such as “about”, “approximately”, or other terms of approximation denote allowable variations that do not materially affect function or performance.

The present invention relates to modulation circuitry for receiving an input control signal and producing, from that input signal, a shaped and conditioned output suitable for driving a wide range of electrical loads. In various embodiments, the load may be an inductive or resistive device such as a motor, pump, actuator, relay, or other electrically operated device. The modulation circuitry is operable to establish amplitude limits, generate clean pulses, and condition the waveform through filtering and biasing so that a controlled switching output is produced. The output may then be used to control a downstream device according to the characteristics of the input signal and/or in accordance with a modified waveform generated by the modulator circuitry.

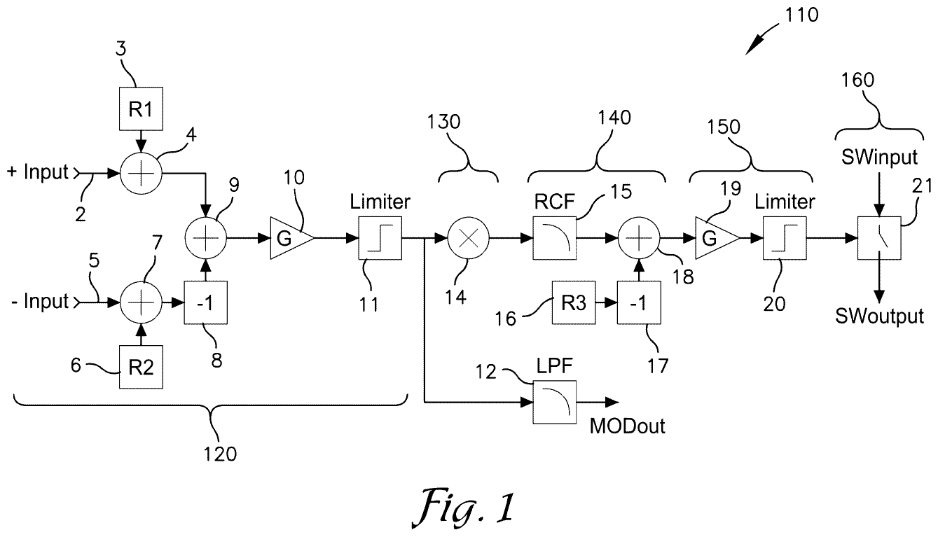

Looking first to FIG. 1, a modulator 110 comprising circuitry in accordance with an exemplary embodiment of the present invention is depicted. As shown, the modulator generally includes an input and limiting amplifier section 120, a detection section 130, a pulse shaping section 140, a timing and filtering section 150, and an output switching section 160. These stages are in electrical communication with each other and are operable to convert a wide variety of input signals into precise shaped and filtered switching outputs suitable for driving an electrical load.

Looking first to input and limiting amplifier section 120, an input control waveform is received at a positive input port 2 and a negative input port 5, each having associated positive and negative reference voltages 3 and 6, respectively. In the depicted embodiment, the input section 120 includes a first summer 4, a second summer 7, a first inverter 8, and a third summer 9, arranged to combine and condition the input signals. A gain/amplifier 10 and limiter 11 establish amplitude boundaries so that the output of the limiting amplifier is only positive (high) when the sum of the positive input port 2 and the positive reference 3 exceeds the sum of the negative input port 5 and the negative reference 6. When this condition is not met, the limiting amplifier output provides a substantially zero (low) output. This high/low output limiting establishes the underlying pulse timing which is used by the subsequent stages of the modulator 110.

The conditioned output of the limiting amplifier section 120 is provided to a low-pass filter (LPF) 12, which, in various embodiments, may generate a DC or a slowly varying output proportional to the duty cycle or frequency of the limiting amplifier output, depending on the mode of operation as will be described in more detail below.

Within the modulator circuitry 110, the conditioned output of the limiting amplifier section 120 is also sent to a detector section 130. As depicted in FIG. 1, the detector section includes half-wave detector 14 operable to detect the positive portions of the waveform and produce a corresponding rectified output. In one embodiment, the detector 14 produces a DC output proportional to the positive peaks of the incoming wave from the limiting amplifier.

At section 140 the wave is shaped and filtered, with the output of the detector section 130 provided to an RC filter 15 which receives the rectified signal and produces a decaying, unshaped pulse whose duration is a function of the RC time constant. The capacitor within the RC filter charges to a maximum value Vₘ corresponding to the detector output, and then discharges through the filter resistor according to the expression: Vₒᵤₜ=Vₘ*e^{(-t/RC)}, where t is time and RC is the time constant of the filter.

The waveform is supplied to a fourth summer 18, which also receives an inverted version of an input reference 16, with the inversion provided by a second inverter 17. The summer 18 produces an intermediate signal proportional to the relationship between the decaying RC output and the reference threshold.

A second gain/amplifier 19 receives the output of summer 18 and provides amplification suitable for triggering the second limiter 20, which clips or shapes the amplified signal to produce a clean pulse that serves as the control input for the output switch. Thus, when the decaying RC voltage Vₘ*e^{(-t/RC)} exceeds the reference threshold, the pulse generator output is high, and when the RC voltage falls below the reference threshold, the output is substantially zero.

The shaped and conditioned waveform is supplied to switch 21 in the output switching section 160. The switch is activated during the time in which the pulse generator output is high, thus providing a switching output suitable for powering a downstream load. Because the timing of the switching output is determined by the RC time constant and limiting amplifier timing, the output may be a continuous signal, a pulse-width modulated (PWM) signal, or pulses of controlled width and frequency.

As just described, the modulator circuit of FIG. 1 supports several modes of operation depending on the input signal frequency, the duty cycle of the input, the cutoff frequency of the low-pass filter 12, and the RC time constant of the pulse generator 15.

In one mode of operation, when the input signal is a fixed frequency but has a variable duty cycle, and the input frequency is greater than the cutoff frequency of the low-pass filter 12, the LPF outputs a DC voltage proportional to the duty cycle of the limiting amplifier output. The duty cycle is defined as the time that the limiting amplifier output is high divided by the period of the input signal.

In another mode of operation, when the input signal comprises a variable frequency but a fixed duty cycle, and the frequency is substantially higher than the cutoff frequency of the LPF 12, the LPF outputs an alternating current (AC) signal with an amplitude proportional to the frequency of the input signal.

In yet another mode of operation, when the time in which the limiting amplifier section 120 output is zero is substantially less than the RC time constant of the pulse generator 15, the output switch 21 remains continuously activated. Thus, the RC decay never falls below the threshold, causing the output to remain high.

And, in another mode of operation, when the input frequency is low enough, and the limiting amplifier output is positive only for periods substantially less than the RC time constant, the modulator produces a PWM signal at the output. In this mode, each short duration positive pulse at the limiting amplifier output causes the pulse generator to produce a pulse whose width is determined by the RC time constant. As the off time decreases (e.g., either via frequency or duty cycle changes), the number of pulses and the output duty cycle increases correspondingly.

It should be understood that the multiple modes of operation as just described may be invoked simultaneously. For example, a high-frequency PWM input (mode one) combined with an off-time shorter than the RC time constant (mode three) will result in a constant on output while still providing a DC signal at the LPF output. Similarly, modes two and three may likewise occur together under appropriate timing conditions. The modulator may also be driven from inverting or non-inverting inputs to produce corresponding inverted behaviors.

In one exemplary mode of operation, modulators according to the present invention as just described may be used in connection with one or more fuel pumps. For example, a PWM input may control the pumping rate of one or more fuel pumps, enabling control of fuel flow to an internal combustion engine in automotive or aerospace applications. In other embodiments, the modulator may be used with PWM drivers by receiving a lower power PWM signal and generating an equivalent higher-power PWM output.

In one preferred embodiment, the positive input port 2 may receive a PWM signal with a duty cycle greater than approximately 1%, with a frequency substantially higher than the cutoff frequency of the LPF 12, and with a period substantially shorter than the RC time constant. In operation under these conditions, the LPF 12 outputs a direct current (DC) voltage proportional to the duty cycle while the switched output is held continuously on. Similar corresponding operation occurs for the negative input port 5 when driven with PWM signals with a duty cycle less than approximately 99%.

In some embodiments, additional and/or alternative signal conditioning may be used on the raw control input signal before applying the control signal to the modulator. For example, a signal may be galvanically or optically isolated from the system or device generating the signal using a transformer or optical isolator for reasons of safety or to simply provide isolation of the modulator from the control system.

As just described, systems and methods in accordance with the present invention can be used to reduce the overall number of connections to outside sources required in connection with an input circuit. In some embodiments, various combinations of switching and modulation outputs can be implemented by using various combinations of input signals as will now be discussed. Thus, it should be understood that the modulator may be incorporated into a wide range of systems in which an input waveform is used to control a downstream electrical device.

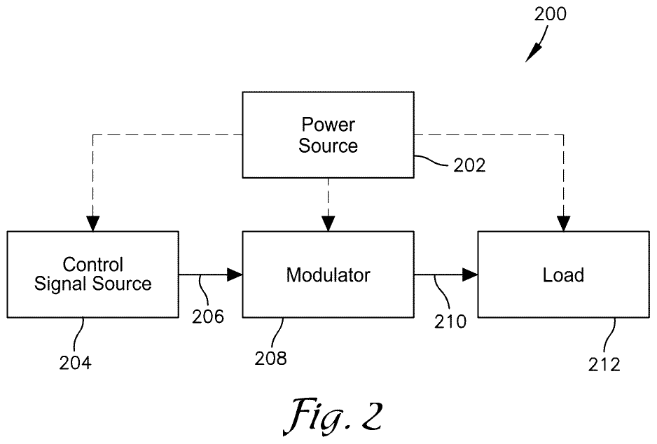

Turning now to FIG. 2, a system 200 in accordance with an exemplary embodiment of the present invention is depicted. In this embodiment, a control signal source 204 provides an incoming waveform 206 to a modulator 208 (i.e., a modulator 110 of FIG. 1 as just described), which processes the waveform through its input and limiting amplifier section 120, detection section 130, pulse shaping section 140, and output switching section 160, as described previously, and produces a corresponding switching output 210 suitable for driving an electrical load 212. A power source 202 may supply AC and/or DC power to any or all of the modules as required.

In one embodiment, the control signal source 204 may be any circuit, controller, or device capable of supplying a repetitive or periodic waveform, such as PWM generators, oscillators, logic level outputs from control systems, or other signal producing control modules. As described above, the modulator 208 receives the signal 206 from the signal source 204 through its input and limiting amplifier section 120, conditions the waveform through its detection and shaping circuitry 130 and 140, establishes the appropriate time-constant behavior through its filtering section 150, and drives a switching element within its output section 160 to modulate output current and/or voltage 210 which is delivered to the electrical load 212.

The electrical load 212 may be an inductive or resistive device such as a motor, pump, actuator, solenoid, or other electrically operated device or component. Because the modulator 110 of FIG. 1 limits amplitude, shapes input pulses, and provides controlled time-constant filtering, the output supplied to the load 212 provides improved stability and predictability of operation as compared to the raw, unconditioned control signal provided directly by source 204. Furthermore, depending on the characteristics of the incoming waveform, the modulator 208 may operate in any of the modes previously described with respect to FIG. 1.

In some embodiments, the system 200 may further include measurement devices such as a current sensor, a voltage monitor, or other diagnostic elements configured to monitor the operation of the load 212 or to provide information to a system controller. The modulator circuitry itself, however, as previously described, does not require feedback or signals from the load 212 to operate, and the depiction of the system in FIG. 2 does not imply any closed-loop control.

The system of FIG. 2 illustrates a single example of how the modulator 110 of FIG. 1 may be integrated with a control signal source and a load. It should be understood that in other embodiments the modulator may be employed in various other system arrangements, including systems using multiple control sources, multiple loads, or additional conditioning circuits upstream or downstream of the modulator circuitry. Variations of the configuration and arrangement as shown in FIG. 2 are within the scope of the present invention so long as the modulator 208 receives an input waveform and supplies a shaped switching output as described above with reference to FIG. 1.

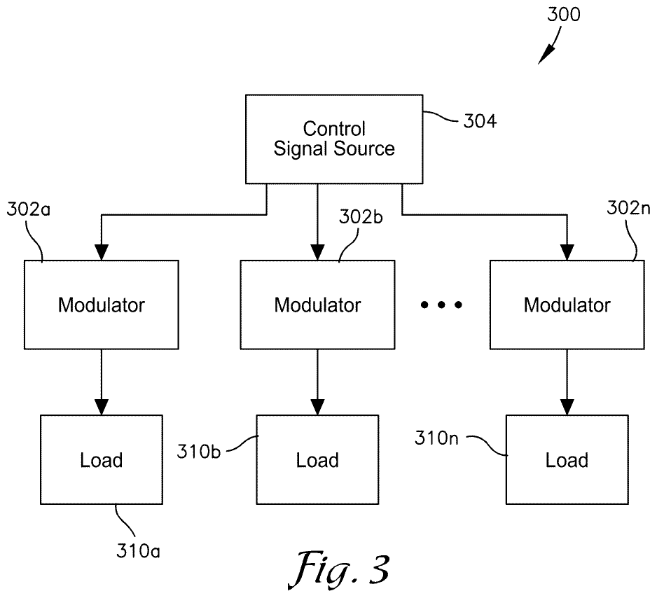

In some embodiments, more than one instance of the modulator may be employed within a system. For example, multiple modulators may be used when it is desired to control multiple loads independently, when different portions of a system require distinct switching characteristics, or when a control source provides several control signals that each must be conditioned separately. Looking to FIG. 3, a multi-load control configuration 300 is depicted in accordance with an exemplary embodiment of the present invention.

In the embodiment shown in FIG. 3, a control signal source 304 provides one or more control input waveforms to a plurality of modulators 302a, 302b, 302n, each configured as the modulator 110 previously described with respect to FIG. 1. Each modulator 302a, 302b, 302n receives an input signal and conditions the incoming signal through its input and limiting amplifier section 120, detection section 130, pulse shaping section 140, timing and filtering section 150, and output switching section 160 as described with respect to FIG. 1 to produce an output waveform suitable for driving a corresponding load.

As seen in FIG. 3, each modulator 302a through 302n receives a separate input signal and drives a separate load 310a, 310b, 310n. It should be understood that the loads may be identical or may be different, and may represent motors, pumps, actuators, or other electrically operated components consistent with the applications previously described. Each modulator thus operates independently, generating the desired switching outputs whose characteristics reflect their respective input signals and the behavior of the internal stages described with reference to FIG. 1.

In some embodiments, the control signal source 304 may generate separate control signals for each modulator, while in other embodiments, a common control signal may be supplied to the multiple modulators. For example, a control system may be configured to supply a single PWM signal to several modulators, each of which may condition the signal and deliver a switching output to a corresponding load. Alternatively, different and/or unique control signals may be provided to each separate modulator so that each modulator operates with its own unique timing characteristics. In either case, each modulator operates using the limiting, shaping, filtering, and switching techniques as previously described.

It should be understood that the arrangement shown in FIG. 3 represents only one example of how multiple modulators may be deployed within a system. In alternative embodiments a control system may control modulated and unmodulated loads, or may incorporate intermediate conditioning stages upstream or downstream of the modulators. Variations in the number, arrangement, and function of the modulators are within the scope of the present invention, provided each modulator receives an input waveform and supplies a shaped switching output as described above with respect to FIG. 1.

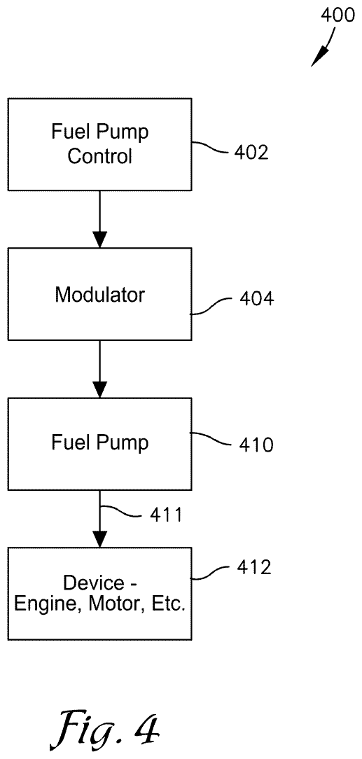

Looking now to FIG. 4, a fuel pump control system 400 is depicted in accordance with an exemplary embodiment of the present invention. The depicted embodiment illustrates how the modulator 110 of FIG. 1 may be utilized to drive a fuel pump or similar electromechanical device whose speed or flow characteristics are governed by a control signal.

In the exemplary embodiment of FIG. 4, a PWM command signal is provided by a pump control source 402, which may be an engine control module, a vehicle control system, an aerospace controller, or another subsystem responsible for regulating fuel delivery to an engine or device requiring fuel to operate. The command signal reflects a desired operational condition, such as a target flow rate, pressure, or pump speed.

In operation, the PWM command signal is supplied to a modulator 404 (e.g., a modulator 110 as described above with respect to FIG. 1), which performs the limiting, detection, shaping, and filtering functions as previously described. Through these processing stages, the modulator conditions the input waveform to produce a shaped switching output suitable for driving an electromechanical fuel pump. The shaped output may include a duty-cycle-dependent or frequency-dependent component consistent with the operational modes described previously, thus allowing the fuel pump to respond predictably to variations in the command signal.

The modulated output of the switching section of the modulator 404 is supplied to a fuel pump 410, which may be an electric pump, motor-driven pump, or other device operable to deliver fuel 411 to a device requiring fuel 412. In some embodiments, the device being supplied fuel may be an internal combustion engine, a turbine engine, or other engine system requiring regulated fuel flow. The shaped switching waveform produced by the modulator 404 drives the pump in accordance with the characteristics of the input signal received from the control source.

It should be understood that the embodiment of FIG. 4 is illustrative and does not limit the system to any particular fuel pump type, engine type, or control subsystem. Additional conditioning stages may be used upstream or downstream of the modulator, and the specific operating characteristics of the pump may vary based on the values selected for the RC time constant, input waveform, or duty-cycle relationships as described herein.

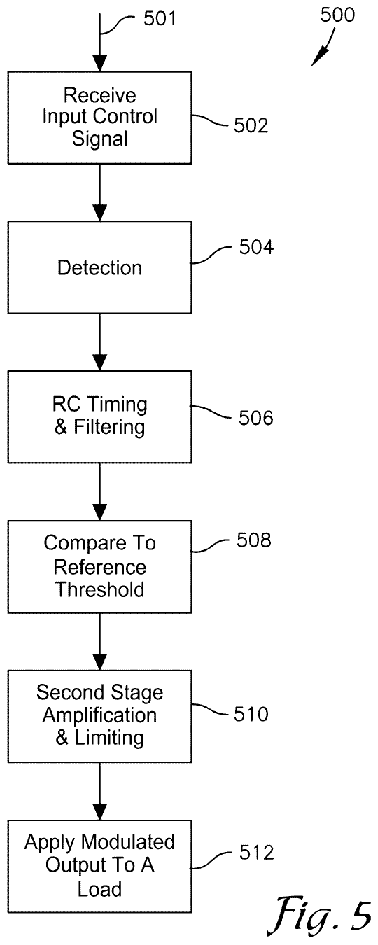

Finally, turning to FIG. 5, a flowchart depicting an exemplary sequence of functional steps performed by the modulator circuitry described with reference to FIG. 1 is shown as 500. It should be understood that the flowchart does not imply that the modulator executes program instructions, instead it provides a representation of how signals progress through the limiting, shaping, filtering, and switching stages of the device. The ordering of the steps shown in FIG. 5 is illustrative, and alternative sequences or equivalent operations may be employed while remaining within the scope of the present invention.

Looking still to FIG. 5, operation begins when an input signal 501 is received at step 502. The input signal may be a PWM signal, a frequency-varying waveform, or another form of periodic or aperiodic control signal consistent with the examples described herein. The signal is provided to the input and limiting amplifier section of the modulator, which limits its amplitude based on the relative values applied to the positive and negative input ports and their respective reference voltages.

At step 504, the limited waveform is directed to the edge detection or half-wave detection performed by the detector section. This step identifies transitions or positive portions of the waveform that are used for driving subsequent shaping and timing operations.

At step 506, the detected pulses are supplied to the RC timing and filtering path of the pulse-shaping section, where a capacitor is charged and allowed to discharge according to the RC time constant. This step produces a decaying waveform whose characteristics correspond to the expression Vₘ*e^{(-t/RC)}, as described previously. The duration of the resulting pulse and the shape of the decay of the pulse are determined by the values of the resistor and capacitor.

At step 508, the decaying waveform is compared against a reference threshold provided by the input reference, thus yielding a shaped pulse whose duration reflects the time interval in which the RC waveform exceeds the threshold. This comparison is performed by the summer 18, inverter 17, and associated shaping elements and components as previously described with reference to FIG. 1.

At step 510, the shaped pulse is amplified and limited by the second gain stage and the second limiter, producing a clean switching control signal suitable for driving the output switching section. This shaped signal defines the timing and duration of the switching output supplied to the load.

At step 512, the output switching section applies the modulated output waveform to a load, such as a fuel pump, motor, pump, actuator, or other device. Depending on the characteristics of the input signal and the relationships between the input waveform, and the RC time constant, the switching output may remain continuously active, generate discrete pulses, or generate a pulse-width-modulated waveform in accordance with the modes of operation as described previously.

It should be understood that FIG. 5 provides a general representation of exemplary functional stages within the modulator and is not intended to limit the device to any particular implementation. Equivalent or rearranged steps may be used, and additional filtering or conditioning steps may be included without departing from the scope of the present invention.

Although the invention has been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A modulation circuit, comprising:
(a) an input and limiting amplifier section comprising:
a first summer, a second summer, a first inverter, and a third summer, wherein the first, second, and third summers are analog summers configured for weighted combination of voltages;
a gain stage, and
a limiter configured to receive a positive input signal and a positive reference, and a negative input signal and a negative reference,
wherein the limiting amplifier section is configured to generate a limited waveform that is high only when a sum of the positive input signal and the positive reference exceeds a sum of the negative input signal and the negative reference, and is substantially zero otherwise;
(b) a detector section comprising a half-wave detector configured to generate a detection output corresponding to positive portions or transitions of the limited waveform;
(c) a timing and filtering section comprising a resistive/capacitive (RC) filter including a capacitor and a resistor, the RC filter configured to charge the capacitor to a maximum value based on the detection output, and discharge the capacitor according to generate a decaying waveform;
(d) a comparison and shaping section comprising an input reference, a second inverter configured to invert the input reference, a fourth summer configured to combine the inverted reference with the decaying waveform, a second gain stage, and a second limiter configured to shape an amplified version of an output of the fourth summer to produce a shaped pulse having a duration corresponding to an interval in which the decaying waveform exceeds the input reference; and
(e) an output switching stage comprising a switching device configured to receive the shaped pulse and generate a switching output for driving an electrical load, wherein the switching device is operable to modulate current supplied to the electrical load.

2. The modulation circuit of claim 1, wherein a low-pass filter coupled to the limiting amplifier section is configured to generate a DC output proportional to a duty cycle of the limited waveform.

3. The modulation circuit of claim 2, wherein the low-pass filter is further configured to generate an AC output having an amplitude proportional to a frequency of the limited waveform.

4. The modulation circuit of claim 1, wherein the switching device comprises a MOSFET, transistor, or electromechanical relay.

5. The modulation circuit of claim 1, wherein an off-time of the limited waveform that is shorter than the RC time constant causes the switching output to remain continuously active.

6. The modulation circuit of claim 1, wherein each short-duration positive transition of the limited waveform generates a shaped pulse whose width is determined by the RC time constant.

7. The modulation circuit of claim 1, wherein the modulation circuit is configured to receive a PWM signal as the positive input signal or the negative input signal.

8. The modulation circuit of claim 1, wherein the shaped pulse comprises a pulse-width-modulated waveform.

9. The modulation circuit of claim 1, wherein the modulation circuit is configured to be driven from inverting or non-inverting inputs to produce correspondingly inverted switching outputs.

10. The modulation circuit of claim 1, further comprising a galvanic or optical isolator configured to isolate the modulation circuit from a control signal source.

11. A method of generating a shaped switching output for driving an electrical load, the method comprising:
(a) receiving an input control signal at a limiting amplifier comprising analog summers, an inverter, a gain stage, and a limiter;
(b) generating, by the limiting amplifier, a limited waveform that is high only when a sum of a positive input and positive reference exceeds a sum of a negative input and negative reference;
(c) detecting, by a half-wave detector, positive portions or transitions of the limited waveform to generate a detection output;
(d) charging a capacitor of an RC filter to a maximum value based on the detection output and discharging the capacitor to generate a decaying waveform;
(e) comparing the decaying waveform to an input reference by combining the decaying waveform with an inverted version of the input reference at a summer;
(f) amplifying and limiting the comparison result to generate a shaped pulse having a duration corresponding to an interval in which the decaying waveform exceeds the reference; and
(g) supplying the shaped pulse to a switching device to generate a switching output for the electrical load.

12. The method of claim 11, wherein the input control signal comprises a PWM signal having a duty cycle greater than approximately one percent.

13. The method of claim 11, wherein detecting positive portions comprises half-wave detection of the limited waveform.

14. The method of claim 11, further comprising producing a continuous switching output when an off time of the limited waveform is shorter than a time constant of the RC filter.

15. The method of claim 11, wherein supplying the shaped pulse produces a pulse-width-modulated switching output.

16. A fuel-pump control system comprising:
a PWM control source configured to generate a PWM command signal representing a desired operational condition of a fuel pump;
a modulation circuit comprising the limiting amplifier section, detector section, RC timing and filtering section, comparison and shaping section, and output switching stage of claim 1, the modulation circuit configured to receive the PWM command signal and to generate a shaped switching output; and
a fuel pump coupled to the output switching stage and configured to receive the shaped switching output and deliver fuel to a fuel-consuming device in accordance with the PWM command signal.

17. The system of claim 16, wherein the fuel pump comprises an electromechanical pump having a winding inductance and winding resistance.

18. The system of claim 16, wherein increases in duty cycle of the PWM command signal produce corresponding increases in an on time of the shaped switching output.

19. The system of claim 16, wherein the shaped switching output comprises a pulse-width-modulated waveform when an off time of the limited waveform is greater than the RC time constant.

20. The system of claim 16, wherein the shaped switching output remains continuously active when an off-time of the PWM command signal is less than the RC time constant.
